(19) United States
(12) Patent Application Publication
(10) Pub. No.: US 2026/0168864 A1
(43) Pub. Date: Jun. 18, 2026

(54) TEMPERATURE MEASURING APPARATUS AND SUBSTRATE PROCESSING APPARATUS

(71) Applicant: SEMES CO., LTD., Cheonan-si (KR)

(72) Inventors: Yong Jun SEO, Hwaseong-si (KR); Sang Hyun SON, Busan (KR); Young Sik BANG, Yongin-si (KR); Ik Ho LEE, Suwon-si (KR); Dong Joo SHIN, Suwon-si (KR); Kwang Sup KIM, Asan-si (KR)

(73) Assignee: SEMES CO., LTD., Cheonan-si (KR)

(21) Appl. No.: 19/423,217

(22) Filed: Dec. 17, 2025

(30) Foreign Application Priority Data
Dec. 18, 2024 (KR) 10-2024-0190121

(51) Int. Cl. G01K 1/02; G01K 1/14; G03F 7/16; H10P 72/00

(52) U.S. Cl. CPC G01K 1/026; G01K 1/14; G03F 7/168; H10P 72/0602; G01K 2215/00

(57) ABSTRACT

Provided are a temperature measuring apparatus and a substrate processing apparatus. The temperature measuring apparatus includes: a base plate on which a plurality of measurement pads is formed; a plurality of sensor units provided on the base plate and electrically connected to the corresponding measurement pad; and a signal processing unit electrically connected to the measurement pads and configured to receive sensing values from the plurality of sensor units, in which the signal processing unit includes: a plate; a signal processing substrate provided on the plate, on which a processor configured to process the sensing value is mounted; and a plurality of legs extending downward from a lower surface of the plate to separate the plate and the base plate from each other.

### CROSS-REFERENCE TO RELATED APPLICATION

This application claims priority to and the benefit of Korean Patent Application No. 10-2024-0190121 in the Korean Intellectual Property Office on Dec. 18, 2024, the entire contents of which are incorporated herein by reference.

### TECHNICAL FIELD

The present invention relates to a temperature measuring apparatus and a substrate processing apparatus, and more particularly, to a temperature measuring apparatus for measuring a temperature of a substrate and a substrate processing apparatus for heat-treating a substrate.

### BACKGROUND ART

In order to manufacture a semiconductor device or a liquid crystal display, various processes, such as photolithography, ashing, etching, ion implantation, thin film deposition, and cleaning, of a substrate may be performed. Among them, the photolithography process is a process for forming a desired pattern on a substrate and plays an important role in achieving high integration of semiconductor devices.

The photolithography process is largely composed of a coating process, an exposure process, and a developing process. In the steps before and after the exposure process is in progress, a bake process is performed. The bake process is a process of heat-treating a substrate, and placing a substrate on a heating plate and heat-treating the substrate using a heater installed inside the heating plate.

In this bake process, it is important to precisely control the temperature of the substrate surface, and the temperature of the substrate surface is generally measured using a temperature sensor. However, the existing temperature sensors have a problem that it is difficult to use in a bake process that requires high temperature due to low heat resistance.

### SUMMARY OF THE INVENTION

The present invention has been made in an effort to provide a temperature measuring apparatus and a substrate processing apparatus capable of measuring a temperature of a substrate surface in a bake process requiring high temperature.

The objectives of the present disclosure are not limited thereto and other objectives not stated herein may be clearly understood by those skilled in the art from the following description.

An exemplary embodiment of the present disclosure, a temperature measuring apparatus comprising: a base plate on which a plurality of measurement pads is formed; a plurality of sensor units provided on the base plate and electrically connected to the corresponding measurement pad; and a signal processing unit electrically connected to the measurement pads and receiving sensing values from the plurality of sensor units, wherein the signal processing unit may includes: a plate; a signal processing substrate provided on the plate, on which a processor for processing the sensing value is mounted; and a plurality of legs extending downward from a lower surface of the plate to separate the plate and the base plate from each other.

According to the exemplary embodiment of the present invention, wherein the signal processing unit further may includes a first heat insulation part provided between the plate and the signal processing substrate.

According to the exemplary embodiment of the present invention, wherein wherein the signal processing unit further includes: a plurality of buffer pads provided on the plate and electrically connected to the corresponding measurement pad through a first wire; and a plurality of signal processing pads mounted on the signal processing substrate and electrically connected to the corresponding buffer pad through a second wire, and the plurality of buffer pads may be provided at an outer side than the first insulation part.

According to the exemplary embodiment of the present invention, wherein an area of the buffer pad may be provided larger than an area of the corresponding measurement pad.

According to the exemplary embodiment of the present invention, wherein the signal processing unit further includes: a cover provided on the plate to cover the signal processing substrate; and a second heat insulation part provided on a sidewall of the cover, and the second heat insulation part may surrounds at least a part of the second wire.

According to the exemplary embodiment of the present invention, wherein when viewed from above, the sidewall of the cover is in contact with an upper surface of the buffer pad, the buffer pad has an inner portion positioned inward of the sidewall and an outer portion positioned outward of the sidewall, the first wire is connected to the outer portion, and the second wire may be connected to the inner portion.

According to the exemplary embodiment of the present invention, further may comprising: a third heat insulation part provided on an inner surface of an upper wall of the cover.

According to the exemplary embodiment of the present invention, wherein at least one of the plurality of sensor units may includes: a sensor substrate embedded in the base plate; a temperature sensor mounted on the sensor substrate; and a sensor pad electrically connected to the corresponding measurement pad through a third wire.

According to the exemplary embodiment of the present invention, wherein at least one of the plurality of sensor units may includes: a temperature sensor mounted on the base plate; and a sensor pad electrically connected to the corresponding measurement pad through a fourth wire.

According to the exemplary embodiment of the present invention, wherein the signal processing unit further may includes a battery that supplies power to the signal processing substrate.

An exemplary embodiment of the present disclosure, an apparatus for processing a substrate, the apparatus comprising: a chamber having an inner space formed; a support unit provided in the inner space to support a substrate; a heater for heating the substrate supported by the support unit; and a temperature measuring apparatus provided to be supportable by the support unit and measuring temperature, wherein the temperature measuring apparatus may includes: a base plate on which measurement pads are formed; a plurality of sensor units provided on the base plate and electrically connected to the measurement pads; and a signal processing unit electrically connected to the measurement pads and receiving sensing values from the plurality of sensor units, and the signal processing unit includes: a plate; a signal processing substrate provided on the plate, on which a processor for processing the sensing value is mounted; and a plurality of legs extending downward from a lower surface of the plate to separate the plate and the base plate from each other.

According to the exemplary embodiment of the present invention, further may comprising: a plurality of buffer pads provided on the plate and electrically connected to the corresponding measurement pad through a first wire; and a plurality of signal processing pads mounted on the signal processing substrate and electrically connected to the corresponding buffer pad through a second wire, and a cover provided on the plate to cover the signal processing substrate; and a first heat insulation part provided between the plate and the signal processing substrate; and a second heat insulation part provided on a sidewall of the cover and surrounding a part of the second wire.

According to the exemplary embodiment of the present invention, wherein an area of the buffer pad may be provided larger than an area of the measurement pad.

According to the exemplary embodiment of the present invention, further may comprising: a third heat insulation part provided on an inner side of an upper wall of the cover.

According to the exemplary embodiment of the present invention, wherein the buffer pad has an inner portion positioned inward of the sidewall and an outer portion positioned outward of the sidewall, the first wire is connected to the outer portion, and the second wire may be connected to the inner portion.

According to the exemplary embodiment of the present invention, wherein at least one of the plurality of sensor units may includes: a sensor substrate embedded in the base plate; a temperature sensor mounted on the sensor substrate; and a sensor pad electrically connected to the corresponding measurement pad through a third wire.

According to the exemplary embodiment of the present invention, wherein at least one of the plurality of sensor units may includes: a temperature sensor mounted on the base plate; and a sensor pad electrically connected to the corresponding measurement pad through a fourth wire.

According to the exemplary embodiment of the present invention, wherein the base plate may has the same shape as the substrate.

An exemplary embodiment of the present disclosure, a temperature measuring apparatus comprising: a base plate on which a plurality of measurement pads is formed; a plurality of sensor units provided on the base plate and electrically connected to the measurement pads; and a signal processing unit electrically connected to the measurement pads and receiving sensing values from the plurality of sensor units, and the signal processing unit includes: a plate; a plurality of buffer pads provided on the plate and electrically connected to the corresponding measurement pad through a first wire; a signal processing substrate provided on the plate, on which a processor for processing the sensing value is mounted; a plurality of signal processing pads mounted on the signal processing substrate and electrically connected to the corresponding buffer pad through a second wire; a cover provided on the plate to cover the signal processing substrate; a first heat insulation part provided between the plate and the signal processing substrate; a second insulation part provided on a sidewall of the cover and surrounding a part of the second wire; a battery for supplying power to the signal processing substrate; and a plurality of legs extending downward from a lower surface of the plate to separate the plate and the base plate from each other, and when viewed from above, the sidewall of the cover is in contact with an upper surface of the buffer pad, the buffer pad has an inner portion positioned inward of the sidewall and an outer portion positioned outward of the sidewall, the first wire is connected to the outer portion, and the second wire may be connected to the inner portion.

According to the exemplary embodiment of the present invention, wherein an area of the buffer pad may be provided larger than an area of the corresponding measurement pad.

According to the exemplary embodiment of the present invention, it is possible to measure a temperature of a substrate surface in a bake process.

According to the exemplary embodiment of the present invention, it is possible to improve heat resistance of a temperature measuring apparatus.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a top plan view of the substrate processing apparatus of FIG. 1 as viewed from a direction A-A.

FIG. 3 is a top plan view of the substrate processing apparatus of FIG. 1 as viewed from a direction B-B.

FIG. 4 is a top plan view of a heat treating chamber illustrated in FIG. 1.

FIG. 5 is a side cross-sectional view of the heat treating chamber illustrated in FIG. 1.

FIG. 6 is a top plan view for describing a baking unit illustrated in FIG. 5.

FIG. 7 is a top plan view schematically illustrating a temperature measuring apparatus according to an exemplary embodiment of the present invention viewed from above.

FIG. 8 is a top plan view of part A of FIG. 7 viewed from the front.

FIG. 9 is a top plan view of part A of FIG. 7 viewed from above.

FIG. 10 is a top plan view of a temperature measuring apparatus according to another exemplary embodiment of the present invention.

FIG. 11 is a top plan view of a temperature measuring apparatus according to still another exemplary embodiment of the present invention.

### DETAILED DESCRIPTION

Hereinafter, exemplary embodiments of the present invention will be described in more detail with reference to the accompanying drawings. The exemplary embodiments of the present invention may be modified in various forms, and the scope of the present invention should not be construed as being limited to the exemplary embodiments described below. The present exemplary embodiment is provided to more completely describe the present invention to a person having average knowledge in the art. Therefore, the shapes of components in the drawings are exaggerated to emphasize a clearer description.

In the present exemplary embodiment, a process of liquid-treating a substrate by supplying a liquid, such as a cleaning solution, onto the substrate will be described as an example. However, the present exemplary embodiment is not limited to the cleaning process, but is applicable to various processes of treating the substrate using a treatment liquid, such as an etching process, an ashing process, and a developing process.

The facility of the present exemplary embodiment may be used to perform a photolithography process on a substrate, such as a semiconductor wafer or a flat panel display panel. In particular, the facility of the present exemplary embodiment may be connected to an exposure apparatus and used to perform a coating process and a developing process on a substrate. Hereinafter, a case in which a wafer is used as the substrate will be described as an example.

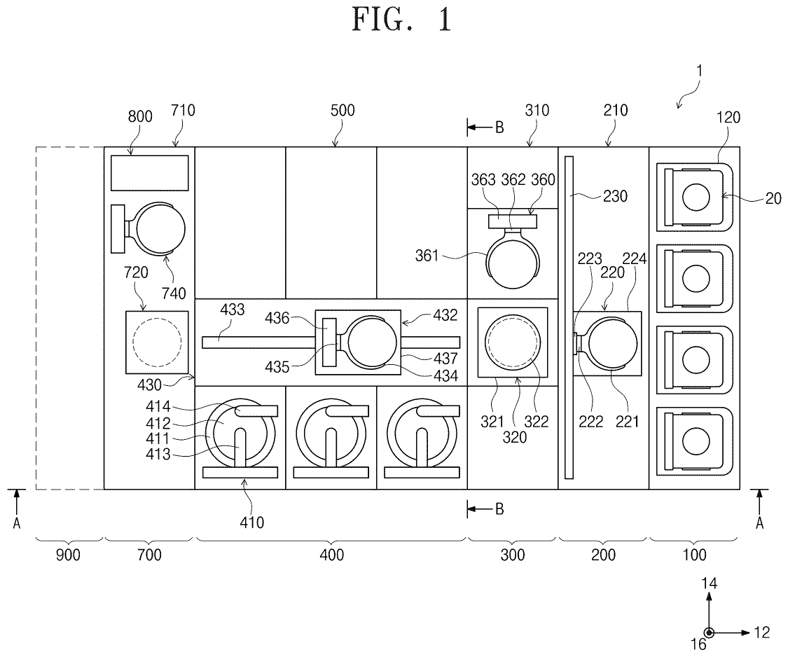

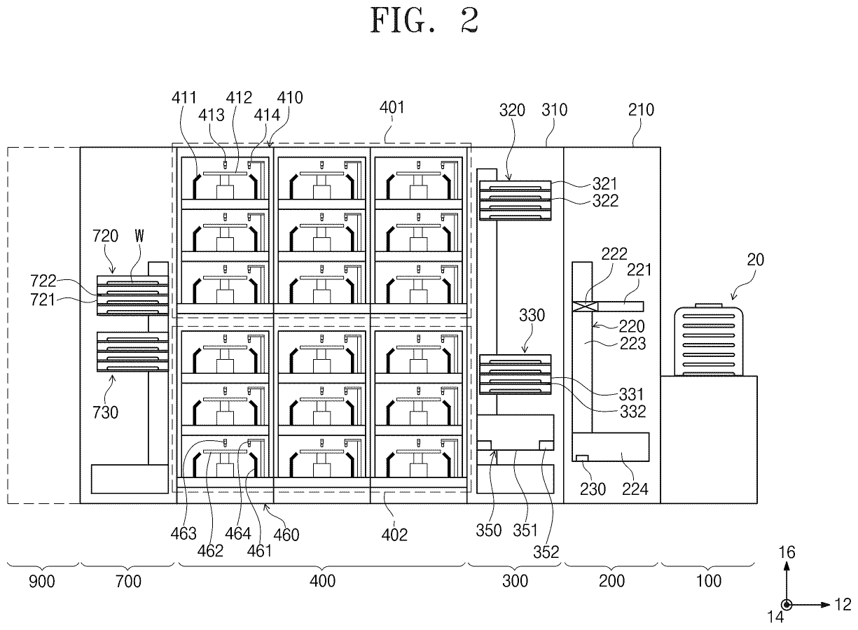

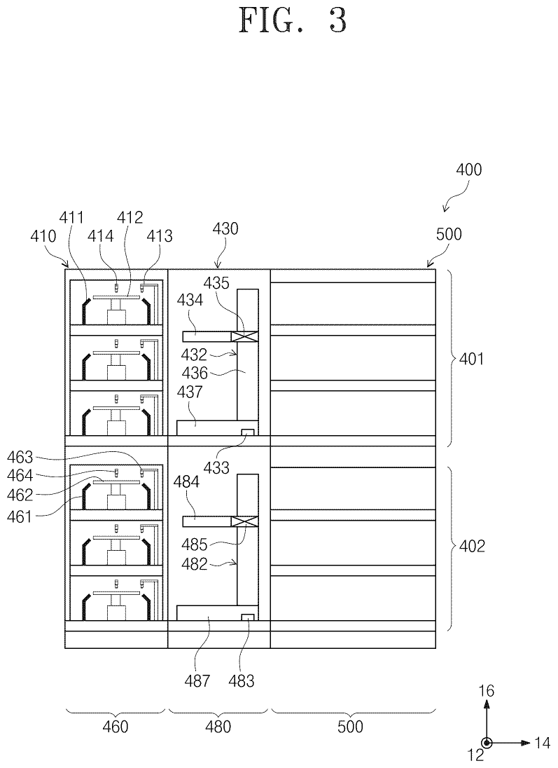

FIGS. 1 to 3 are top plan views schematically illustrating a substrate processing apparatus according to an exemplary embodiment of the present invention. FIG. 1 is a top plan view schematically illustrating a substrate processing apparatus according to an exemplary embodiment of the present invention, FIG. 2 is a top plan view of the substrate processing apparatus of FIG. 1 as viewed from a direction A-A, and FIG. 3 is a top plan view of the substrate processing apparatus of FIG. 1 as viewed from a direction B-B.

Referring to FIGS. 1 to 3, a substrate processing apparatus 1 includes a load port 100, an index module 200, a buffer module 300, a coating and developing module 400, an interface module 700, and a purge module 800. The load port 100, the index module 200, the buffer module 300, the coating and developing module 400, and the interface module 700 are sequentially arranged in a line in one direction. The purge module 800 may be provided in the interface module 700. Alternatively, the purge module 800 may be provided at various positions, such as a position to which an exposure device at a rear end of the interface module 700 is connected, or a side portion of the interface module 700.

Hereinafter, a direction in which the load port 100, the index module 200, the buffer module 300, the coating and developing module 400, and the interface module 700 are arranged is referred to as a first direction 12. When viewed from above, a direction perpendicular to the first direction 12 is defined as a second direction 14, and a direction perpendicular to both the first direction 12 and the second direction 14 is defined as a third direction 16.

The substrate W is moved while being accommodated in a cassette 20. The cassette 20 has a structure that may be sealed from the outside. For example, a Front Open Integrated Pod (FOUP) having a door at the front may be used as the cassette 20.

Hereinafter, the load port 100, the index module 200, the buffer module 300, the coating and developing module 400, the interface module 700, and the purge module 800 will be described.

The load port 100 has a placement table 120 on which the cassette 20 in which the substrates W are accommodated is placed. A plurality of placement tables 120 is provided, and the placement tables 120 are arranged in a row in the second direction 14. In FIG. 1, four placement tables 120 are provided.

The index module 200 transfers the substrate W between the buffer module 300 and the cassette 20 placed on the placement table 120 of the load port 100. The index module 200 includes a frame 210, an index robot 220, and a guide rail 230. The frame 210 is generally provided in a rectangular parallelepiped shape having an empty inside. The frame 210 is disposed between the load port 100 and the buffer module 300. The frame 210 of the index module 200 may be provided at a lower height than the frame 310 of the buffer module 300 to be described later. The index robot 220 and the guide rail 230 are disposed within the frame 210. The index robot 220 has a structure capable of performing 4-axis driving so that the hand 221 that directly handles the substrate W may move and rotate in the first direction 12, the second direction 14, and the third direction 16. The index robot 220 includes a hand 221, an arm 222, a support 223, and a base 224. The hand 221 is fixedly installed at the arm 222. The arm 222 is provided in a stretchable structure and a rotatable structure. The support 223 is disposed such that its longitudinal direction is along the third direction 16. The arm 222 is coupled to the support 223 to be movable along the support 223. The support 223 is fixedly coupled to the base 224. The guide rail 230 is provided such that its longitudinal direction is disposed along the second direction 14. The base 224 is coupled to the guide rail 230 to be linearly movable along the guide rail 230. Also, although not illustrated, the frame 210 is further provided with a door opener for opening and closing the door of the cassette 20.

The buffer module 300 includes a frame 310, a first buffer 320, a second buffer 330, a sensor storage unit 350, and a first buffer robot 360. The frame 310 is provided in a rectangular parallelepiped shape having an empty inside, and is disposed between the index module 200 and the coating and developing module 400. The first buffer 320, the second buffer 330, the sensor storage unit 350, and the first buffer robot 360 are located within the frame 310. The sensor storage unit 350, the second buffer 330, and the first buffer 320 are sequentially disposed from the bottom along the third direction 16. The first buffer 320 is positioned at a height corresponding to a coating module 401 of the coating and developing module 400 to be described later, and the second buffer 330 and the sensor storage unit 350 are provided at a height corresponding to a developing module 402 of the coating and developing module 400 to be described later. The first buffer robot 360 is positioned to be spaced apart from the second buffer 330, the sensor storage unit 350, and the first buffer 320 by a predetermined distance in the second direction 14

Each of the first buffer 320 and the second buffer 330 temporarily stores a plurality of substrates W. The second buffer 330 includes a housing 331 and a plurality of supports 332. The supports 332 are disposed within the housing 331 and are provided to be spaced apart from each other along the third direction 16. One substrate W is placed in each of the supports 332. The housing 331 has openings (not illustrated) in a direction in which the index robot 220 is provided and a direction in which the first buffer robot 360 is provided so that the index robot 220 and the first buffer robot 360 may load or unload the substrate W into or from the support 332 within the housing 331. The first buffer 320 has a structure substantially similar to that of the second buffer 330. However, the housing 321 of the first buffer 320 has openings in a direction in which the first buffer robot 360 is provided and a direction in which a coating unit robot 432 located on the coating module 401 is provided. The number of supports 322 provided in the first buffer 320 may be the same as or different from the number of supports 332 provided in the second buffer 330. According to an example, the number of supports 332 provided to the second buffer 330 may be greater than the number of supports 322 provided to the first buffer 320. Also, the first buffer 320 and the second buffer 330 include a cooling unit. The cooling unit cools the substrate W by a cooling unit. Various methods, such as cooling by coolant or cooling by using a thermoelectric element, may be used as the cooling means.

The sensor storage unit 350 stores a temperature measuring apparatus 2000, which will be described later. The sensor storage unit 350 has openings (not illustrated) in the direction in which the index robot 220 is provided and the direction in which the first buffer robot 360 is provided so that the index robot 220 and the first buffer robot 360 may load or unload the substrate W into or from the support 352 in the housing 351.

The first buffer robot 360 transfers the substrate W between the first buffer 320 and the second buffer 330. Also, the first buffer robot 360 may transfer the temperature measuring apparatus 2000 between the second buffer 330 and the sensor storage unit 350. The first buffer robot 360 includes a hand 361, an arm 362, and a support 363. The hand 361 is fixedly installed at the arm 362. The arm 362 is provided in a stretchable structure so that the hand 361 may move along the second direction 14. The arm 362 is coupled to the support 363 so as to be able to move linearly in the third direction 16 along the support 363. The support 363 has a length extending from a position corresponding to the second buffer 330 to a position corresponding to the first buffer 320. The support 363 may be provided to be longer in the upper or lower direction. The first buffer robot 360 may be provided such that the hand 361 is driven only in two axes along the second direction 14 and the third direction 16.

The coating module 401 includes a process of coating the substrate W with a photosensitive solution, such as a photoresist, and a heat treatment process, such as heating and cooling the substrate W before and after the resist coating process. The coating module 401 includes a liquid treating chamber 410, a heat treating chamber 500, and a transfer chamber 430. The liquid treating chamber 410, the heat treating chamber 500, and the transfer chamber 430 are sequentially disposed along the second direction 14. The liquid treating chamber 410 may be provided as a resist coating chamber 410 performing the substrate W DP resist coating process. A plurality of resist coating chambers 410 is provided, and a plurality of resist coating chambers 410 are provided, respectively, in the first direction 12 and the third direction 16. A plurality of heat treating chambers 500 are provided, respectively, in the first direction 12 and the third direction 16.

The transfer chamber 430 is positioned in parallel with the first buffer 320 of the first buffer module 300 in the first direction 12. The coating unit robot 432 and the guide rail 433 are positioned in the transfer chamber 430. The transfer chamber 430 has a substantially rectangular shape. The coating unit robot 432 transfers the substrate W between the heat treating chambers 500, the resist coating chambers 410, and the first buffer 320 of the first buffer module 300. The guide rail 433 is disposed such that the longitudinal direction thereof is parallel to the first direction 12. The guide rail 433 guides the coating unit robot 432 to move linearly in the first direction 12. The coating unit robot 432 has a hand 434, an arm 435, a support 436, and a base 437. The hand 434 is fixedly installed at the arm 435. The arm 435 is provided in a stretchable structure so that the hand 434 may move in a horizontal direction. The support 436 is disposed such that its longitudinal direction is along the third direction 16. The arm 435 is coupled to the support 436 so as to be able to move linearly in the third direction 16 along the support 436. The base 436 is fixedly coupled to the support 437, and the base 437 is coupled to the guide rail 433 so as to be movable along the guide rail 433.

All of the resist coating chambers 410 have the same structure. However, the types of photoresists used in each resist coating chamber 410 may be different from each other. As an example, a chemically amplification resist may be used as a photoresist. The resist coating chamber 410 applies a photoresist on the substrate W. The resist coating chamber 410 includes a housing 411, a support plate 412, and a nozzle 413. The housing 411 has a cup shape with an open top. The support plate 412 is located in the housing 411 and supports the substrate W. The support plate 412 is provided to be rotatable. The nozzle 413 supplies a photoresist onto the substrate W placed on the support plate 412. The nozzle 413 has a circular tubular shape, and may supply a photoresist to the center of the substrate W. Optionally, the nozzle 413 has a length corresponding to the diameter of the substrate W, and a discharge port of the nozzle 413 may be provided as a slit. In addition, a nozzle 414 for supplying a cleaning solution, such as deionized water, to clean the surface of the substrate W to which the photoresist is applied may be further provided in the resist coating chamber 410.

The developing module 402 includes a developing process of removing a part of the photoresist by supplying a developer onto the substrate W to obtain a pattern, and a heat treatment process, such as heating and cooling, performed on the substrate W before and after the developing process. The developing module 402 has a liquid treating chamber 460, a heat treating chamber 500, and a transfer chamber 480. The liquid treating chamber 460, the heat treating chamber 500, and the transfer chamber 480 are sequentially disposed along the second direction 14. The liquid treating chamber 460 may be provided as a developing chamber. The developing chamber 460 and the heat treating chamber 500 are spaced apart from each other in the second direction 14 with the transfer chamber 480 interposed therebetween. A plurality of developing chambers 460 is provided, and a plurality of developing chambers 460 are provided in each of the first direction 12 and the third direction 16.

The transfer chamber 480 is positioned in parallel with the second buffer 330 of the first buffer module 300 in the first direction 12. A developing unit robot 482 and a guide rail 483 are positioned in the transfer chamber 480. The transfer chamber 480 has a substantially rectangular shape. The developing unit robot 482 transfers the substrate W between the baking units 1000, the developing chambers 460, and the second buffer 330 and the sensor storage unit 350 of the first buffer module 300. The guide rail 483 is disposed such that the longitudinal direction thereof is parallel to the first direction 12. The guide rail 483 guides the developing unit robot 482 to move linearly in the first direction 12. The developing unit robot 482 has a hand 484, an arm 485, a support 486, and a base 487. The hand 484 is fixedly installed on the arm 485. The arm 485 is provided in a stretchable structure so that the hand 484 may move in a horizontal direction. The support 486 is disposed such that its longitudinal direction is along the third direction 16. The arm 485 is coupled to the support 486 so as to be able to move linearly in the third direction 16 along the support 486. The support 486 is fixedly coupled to the base 487. The base 487 is coupled to the guide rail 483 to be linearly movable along the guide rail 483.

All of the developing chambers 460 have the same structure. The types of developers used in each of the first developing chambers 460 may be different from each other. The developing chamber 460 removes a region irradiated with light from the photoresist on the substrate W. In this case, the region of a protective film irradiated with light is also removed. Depending on the type of photoresist selectively used, only a region not irradiated with light among regions of the photoresist and the protective film may be removed.

The developing chamber 460 has a housing 461, a support plate 462, and a nozzle 463. The housing 461 has a cup shape with an open top. The support plate 462 is located in the housing 461 and supports the substrate W. The support plate 462 is provided to be rotatable. The nozzle 463 supplies a developer onto the substrate W placed on the support plate 462. The nozzle 463 has a circular tubular shape, and may supply a developer to the center of the substrate W. Optionally, the nozzle 463 has a length corresponding to the diameter of the substrate W, and a discharge port of the nozzle 463 may be provided as a slit. In addition, a nozzle 464 for supplying a cleaning solution, such as deionized water, to clean the surface of the substrate W to which the developer has been supplied may be further provided in the developing chamber 460.

The heat treating chamber provided to the developing module 402 is provided substantially the same as the baking unit 1000 described above.

As described above, in the coating and developing module 400, the coating module 401 and the developing module 402 are provided to be separated from each other. Also, when viewed from the top, the coating module 401 and the developing module 402 may have the same chamber arrangement.

The interface module 700 transfers the substrate W. The interface module 700 includes a frame 710, a first buffer 720, a second buffer 730, and an interface robot 740. The first buffer 720, the second buffer 730, and the interface robot 740 are located in the frame 710. The first buffer 720 and the second buffer 730 are spaced apart from each other by a predetermined distance and are disposed to be stacked on each other. The first buffer 720 is disposed higher than the second buffer 730.

The interface robot 740 is spaced apart from the first buffer 720 and the second buffer 730 in the second direction 14. The interface robot 740 transports the substrate W between the first buffer 720, the second buffer 730, and the exposure device 900.

The first buffer 720 temporarily stores the substrates W on which the process has been performed before being moved to the exposure device 900. Further, the second buffer 730 temporarily stores the substrates W for which the process has been completed in the exposure device 900 before they are moved. The first buffer 720 includes a housing 721 and a plurality of supports 722. The supports 722 are disposed within the housing 721 and are provided to be spaced apart from each other along the third direction 16. One substrate W is placed in each of the supports 722. The housing 721 has openings in a direction in which the interface robot 740 is provided and a direction in which a preprocessing robot 632 are provided so that the interface robot 740 and the preprocessing robot 632 may load and unload the substrate W into or from the housing 721. The second buffer 730 has a structure substantially similar to that of the first buffer 720. As described above, only the buffers and the robot may be provided in the interface module without providing a chamber that performs a predetermined process on the wafer.

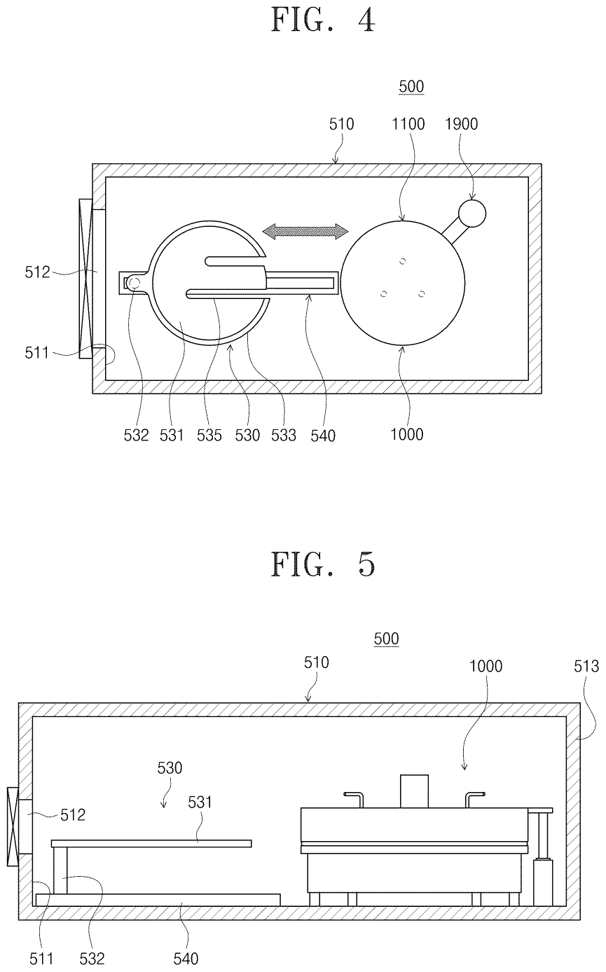

FIG. 4 is a top plan view of a heat treating chamber illustrated in FIG. 1, and FIG. 5 is a side cross-sectional view of the heat treating chamber illustrated in FIG. 1.

Referring to FIGS. 4 and 5, the heat treating chamber 500 includes a housing 510, a cooling unit 530, and a baking unit 1000.

The housing 510 provides an inner space. The housing 510 is provided in a rectangular parallelepiped shape. The housing 510 includes a first sidewall 511, a second sidewall 513, and an entrance 512. The cooling unit 530 and the baking unit 1000 are arranged in parallel in the housing.

The first sidewall 511 is provided on one side surface of the housing 510. The second sidewall 513 is provided opposite the first sidewall 511. The first sidewall 511 of the housing 510 is formed with an entrance 512 through which the substrate W enters and exits. The entrance 512 provides a passage through which the substrate W moves.

The cooling unit 530 cools the substrate W which has been treated in the baking unit 1000. The cooling unit 530 may include a cooling plate 531 and a transfer unit 540 for moving the cooling plate 531. For example, the cooling plate 531 may be provided with a cooling flow path therein. The coolant is supplied to the cooling flow path to cool the substrate W and the cooling plate 531. The transfer unit 540 transfers the cooling plate 531 within the housing 510. The cooling plate 531 may be moved to the standby position and the cooling position by the transfer unit 540. The standby position may be a position adjacent to the entrance (a position illustrated in FIG. 4), and the cooling position may be a position corresponding to an upper portion of the heating plate.

The substrate W is placed on the hand 531. The cooling plate 531 is provided in a circular shape. The cooling plate 531 is provided in the same size as the substrate W. The cooling plate 531 is made of a metal material having good thermal conductivity. A guide hole 535 is formed in the cooling plate 531. The guide hole 535 is provided to extend from the outer surface of the cooling plate 531 toward the inside thereof. The guide hole 535 prevents interference or collision with a lift pin 553 during the movement of the cooling plate 531. A flow path through which a cooling refrigerant flows may be provided in the cooling plate 531.

The arm 532 is fixedly coupled to the cooling plate 531. The arm 532 is provided between the cooling plate 531 and the transfer unit 540.

The transfer unit 540 drives the cooling plate 531. The transfer unit 540 moves the cooling plate 531 horizontally or vertically. The transfer unit 540 may move the cooling plate 531 to a first position and a second position. The first position is a position where the cooling plate 531 is adjacent to the first sidewall 511. The second position is close to the second sidewall 513 and is an upper position of the heating plate.

The baking unit 1000 heat-treats the substrate W. The baking unit 1000 heat-treats the substrate W before and after applying the photosensitive liquid. The baking unit 1000 may heat the substrate W to a predetermined temperature to change the surface properties of the substrate W before applying the photosensitive liquid, and form a treatment liquid film, such as an adhesive, on the substrate W. The baking unit 1000 will be described in detail as follows.

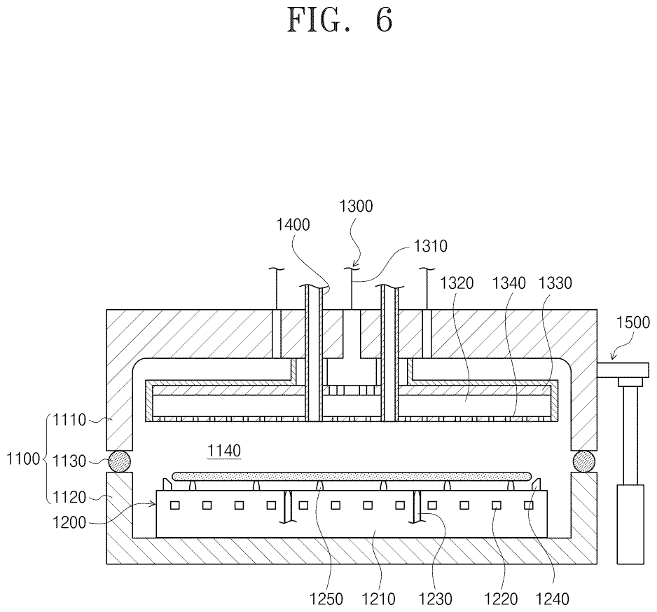

FIG. 6 is a top plan view for describing the baking unit illustrated in FIG. 5.

Referring to FIG. 6, the baking unit 1000 includes a housing 1100, a support unit 1200, a gas supply unit 1300, an exhaust unit 1400, and a driving unit 1500.

The housing 1100 may include an upper chamber 1110, a lower chamber 1120, and a sealing member 1130. The upper chamber 1110 may have a cylindrical shape with an open lower portion. The lower chamber 1120 may have a cylindrical shape with an open upper portion. The lower chamber 1120 may be disposed under the upper chamber 1110. The upper chamber 1110 and the lower chamber 1120 may be combined to form an inner space 1140.

The sealing member 1130 is located between the upper chamber 1110 and the lower chamber 1120. The sealing member 1130 seals the inner space 1140 from the outside when the upper chamber 1110 and the lower chamber 1120 contact each other. The sealing member 1130 may be provided in a ring-shaped shape. The sealing member 1130 may be fixedly coupled to the upper end of the lower chamber 1120.

The support unit 1200 supports the substrate W in the inner space 1140. Also, the support unit 1200 may heat the substrate W. Here, the substrate W may be a temperature measuring apparatus, which will be described later.

The support unit 1200 is fixedly coupled to the lower chamber 1120. The support unit 1200 may include a support plate 1210, a heater 1220, a lift pin 1230, a guide 1240, and a support pin 1250.

The support plate 1210 is provided in a circular plate shape. The upper surface of the support plate 1210 may have a larger diameter than the substrate W. The upper surface of the support plate 1210 may function as a seating surface on which the substrate W is placed. Also, a heater 1220 may be provided on the support plate 1210. The heater 1220 may heat the substrate W. Also, a plurality of heaters 1220 may be provided. A plurality of heaters 1220 may heat the substrate W at different temperatures for each region. For example, some of the plurality of heaters 1220 may heat the center region of the substrate W at a first temperature, and another part of the plurality of heaters 1220 may heat the middle and edge regions of the substrate W at a second temperature. The first temperature and the second temperature may be different from each other.

The lift pin 1230 may vertically move the substrate W. A plurality of lift pins 1230 may be provided. The lift pin 1230 may vertically move the substrate W when loading or unloading the substrate W into or from the inner space 1140.

The guide 1240 guides the substrate W so that the substrate W is placed at the correct position of the seating surface. The guide 1240 is provided to have an annular ring shape surrounding the seating surface. The guide 1240 has a larger diameter than the substrate W. The inner surface of the guide 1240 has a shape inclined downward as it approaches the central axis of the support plate 1210. Accordingly, the substrate W spanning the inner surface of the guide 1240 is moved to the correct position along the inclined surface. In addition, the guide 1240 may prevent a small amount of airflow flowing into a space between the substrate W and the seating surface.

The support pin 1250 may be provided on an upper portion of the support plate 1210. A plurality of support pins 1250 may be provided. The support pins 1250 may be provided to be spaced apart from each other. The support pins 1250 may support a bottom surface of the substrate W. The support pin 1250 may prevent the substrate W from being in direct contact with the support plate 1210.

The gas supply unit 1300 is provided in an upper chamber 1110. The gas supply unit 1300 supplies gas to the inner space 1140. The gas supply unit 1300 injects gas to the substrate W supported by the support unit 1300. The gas may be outside air or clean air. Also, the gas may be gas of which temperature and humidity are controlled. The gas supply unit 1300 forms a descending airflow in the inner space 1140.

The gas supply unit 1300 includes a gas supply line 1310, a gas supply space 1320, a gas heater 1330, and a gas distribution plate 1340.

The gas supply line 1310 is connected to a gas supply source (not illustrated). The gas supply line 1310 receives gas from a gas supply source. The gas supply line 1310 supplies the received gas to the gas supply space 1320.

The gas supply space 1320 is a space formed by combining the gas heater 1330 and the gas distribution plate 1340. The gas supply space 1320 receives gas from the gas supply line 1310. The gas heater 1330 is installed above the gas supply space 1320. The gas heater 1330 heats the gas supplied to the gas supply space 1320. The gas distribution plate 1340 is provided below the gas supply space 1320.

The gas supplied to the gas supply space 1320 is heated by the gas heater 1330 and supplied to the upper portion of the inner substrate W through the distribution plate 1340. The gas supplied to the upper portion of the substrate W volatilizes the film applied on the substrate W. Accordingly, the thickness of the film formed on the substrate W is adjusted.

The exhaust unit 1400 is provided in an upper chamber 1110. The exhaust unit 1400 exhausts the inner space 1140. Also, the exhaust unit 1400 may form a rising airflow in the inner space 1140. The exhaust unit 1400 forms an airflow in the inner space 1140 to volatilize the film applied on the substrate W. Accordingly, the thickness of the film formed on the substrate W is adjusted.

The driver 1500 is fixedly coupled to the upper chamber 1110 by a support unit. When the substrate W is transferred to the support unit 1200, the driver 1500 lifts up and down the upper chamber 1110. As an example, the driver 1500 may be provided as a cylinder.

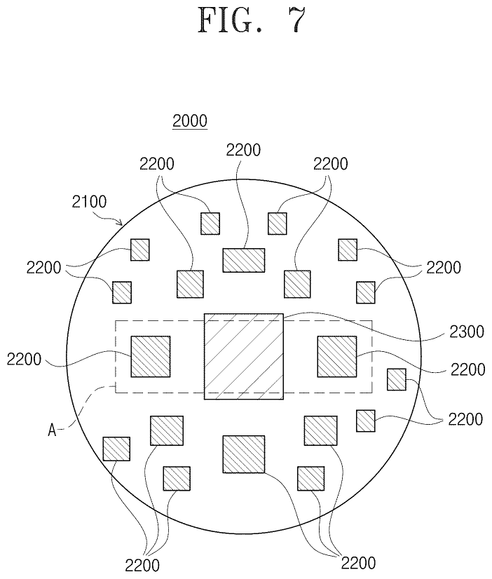

FIG. 7 is a top plan view schematically illustrating a temperature measuring apparatus according to an exemplary embodiment of the present invention viewed from above.

Referring to FIG. 7, the temperature measuring apparatus 2000 includes a base plate 2100, a plurality of sensor units 2200, and a signal processing unit 2300.

The base plate 2100 may have the same shape as the substrate W. For example, the substrate W may be a circular wafer, and the base plate 210 may be a circular plate having the same diameter as the substrate W. Accordingly, the base plate 2100 may be transferred by a transfer robot (for example, the developing unit robot 482) that transfers a substrate.

A plurality of sensor units 2200 is mounted on the base plate 2100. A plurality of sensor units 2200 senses the temperature of the base plate 2100. A plurality of sensor units 2200 transmits sensing values to the signal processing unit 2300. The signal processing unit 2300 receives the sensing values from a plurality of sensor units 2200 and processes the received sensing values. Hereinafter, the temperature measuring apparatus will be described in detail based on region A of FIG. 7.

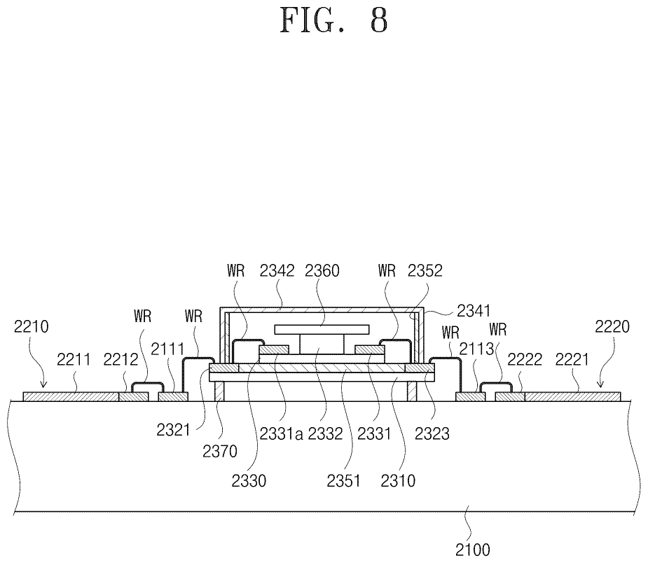

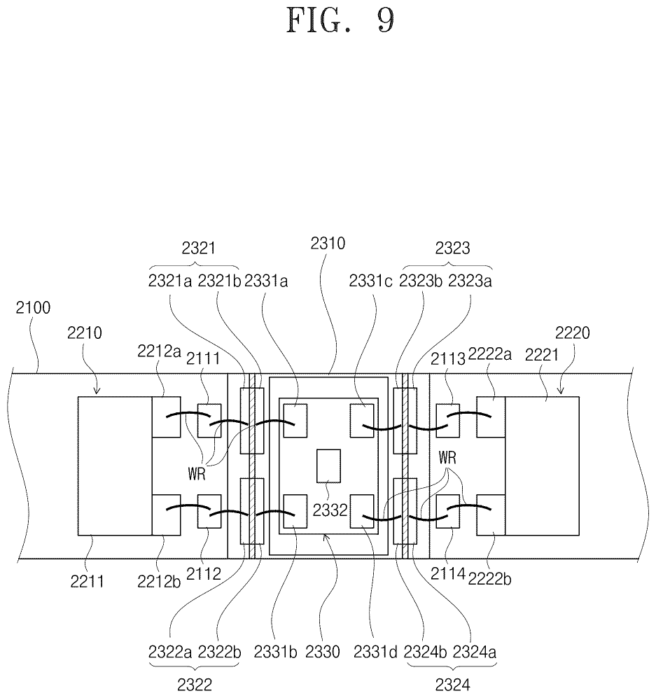

FIG. 8 is a top plan view of part A of FIG. 7 viewed from the front. FIG. 9 is a top plan view of part A of FIG. 7 viewed from above.

Referring to FIGS. 8 to 9, the temperature measuring apparatus 2000 includes the base plate 2100, the plurality of sensor units 2200, and the signal processing unit 2300.

A plurality of measurement pads 2110 is formed on the base plate 2100. A plurality of measurement pads 2110 are formed of a conductive material. For example, a plurality of measurement pads 2110 may be formed of gold (Au). A plurality of measurement pads 2110 include a first measurement pad 2111, a second measurement pad 2112, a third measurement pad 2111 and a fourth measurement pad 2114. Although only four measurement pads are illustrated as the plurality of measurement pads 2110, this is an example and the present invention is not limited thereto. The first measurement pad 2111 and the second measurement pad 2112 are provided at one side with respect to the center of the base plate 2100, and the third measurement pad 2113 and the fourth measurement pad 2114 are provided at the other side with respect to the center of the base plate 2100.

A plurality of sensor units 2200 is provided on the base plate 2100. In the drawings, the plurality of sensor units 2200 are described as being provided outside the base plate 2100, but unlike this, the plurality of sensor units 2200 may be disposed on the entire region of the base plate 2100.

The plurality of sensor units 2200 is electrically connected to the plurality of measurement pads 2110 through wires WR. A plurality of sensor units 2200 includes a first sensor unit 2210 and a second sensor unit 2220. Although only two sensor units as a plurality of sensor units 2200 are illustrated in the drawing, this is an example and the present invention is not limited thereto.

The first sensor unit 2210 includes a temperature sensor 2211 and a plurality of sensor pads 2212.

The temperature sensor 2211 is mounted on the base plate 2100. The temperature sensor 2211 senses a temperature. For example, the temperature sensor 2211 may sense a temperature at one location of the base plate 2100 corresponding to a location where the temperature sensor 2111 is mounted.

A plurality of sensor pads 2212 are formed at an inner side compared to the temperature sensor 2211. A plurality of sensor pads 2212 is connected to the temperature sensor 2211. Although the plurality of sensor pads 2212 and the temperature sensor 2211 are illustrated to be physically connected to each other, in contrast, the plurality of sensor pads 2212 and the temperature sensor 2211 may be electrically connected to each other through wires. A plurality of sensor pads 2212 is formed of a conductive material. For example, a plurality of sensor pads 2212 may be formed of gold (Au).

A plurality of sensor pads 2212 includes a first sensor pad 2212a and a second sensor pad 2212b. Although only two sensor pads are illustrated as the plurality of sensor pads 2212 in the drawing, this is an example and the present invention is not limited thereto. The first sensor pad 2212a and the second sensor pad 2212b correspond to the first measurement pad 2111 and the second measurement pad 2112. The first sensor pad 2212a and the second sensor pad 2212b are electrically connected to the first measurement pad 2111 and the second measurement pad 2112 through a wire WR, respectively.

In one exemplary embodiment, the second sensor unit 2220 may be configured in the same manner as the first sensor unit 2210. Detailed descriptions of the second sensor unit 2220 will be omitted.

The signal processing unit 2300 is installed on a central portion of the base plate 2100. The signal processing unit 2300 is electrically connected to a plurality of measurement pads 2110. The signal processing unit 2300 receives sensing values from the plurality of sensor units 2220 through the plurality of measurement pads 2110, and processes the sensing values.

The signal processing unit 2300 includes a plate 2310, a plurality of buffer pads 2320, a signal processing substrate 2330, a cover 2340, a heat insulation part 2350, a battery 2360, and a plurality of legs 2370.

The plurality of buffer pads 2320 is provided on the plate 2310. The plurality of buffer pads 2320 is provided outside the plate 2310. The area of the plurality of buffer pads 2320 is larger than the area of the plurality of measurement pads 2110 corresponding to the plurality of buffer pads 2320, respectively. The plurality of buffer pads 2320 is formed of a conductive material. For example, a plurality of buffer pads 2320 may be formed of gold (Au). A plurality of buffer pads 2320 is electrically connected to the plurality of measurement pads 2110 through the wire WR.

When viewed from above, the plurality of buffer pads 2320 is divided into an outer portion 2320a and an inner portion 2320b by the cover 2350. The outer portion 2320a is located at the outside with respect to the cover 2350, and the inner portion 2320b is located at the inside with respect to the cover 2350.

The plurality of buffer pads 2320 includes a first buffer pad 2321, a second buffer pad 2322, a third buffer pad 2323, and a fourth buffer pad 2324. Although only four buffer pads are illustrated as the plurality of buffer pads 2320 in the drawing, this is an example, and the buffer pads 2320 may be provided in a number corresponding to the number of the plurality of measurement pads 2110.

The first buffer pad 2321 and the second buffer pad 2322 are provided at one side with respect to the center of the signal processing substrate 2330, and the third buffer pad 2323 and the fourth buffer pad 2324 are provided at one side with respect to the center of the signal processing substrate 2330.

The first buffer pad 2321, the second buffer pad 2322, the third buffer pad 2323, and the fourth buffer pad 2324 correspond to the first measurement pad 2111, the second measurement pad 2112, the third measurement pad 2111 and the fourth measurement pad 2114, respectively.

The first buffer pad 2321, the second buffer pad 2322, the third buffer pad 2323, and the fourth buffer pad 2324 are electrically connected to the first measurement pad 2111, the second measurement pad 2112, the third measurement pad 2111 and the fourth measurement pad 2111 through the wire WR. Here, the wire WR is connected to the outer portions 2321a, 2322a, 2323a, 2323a, and 2324a of the first buffer pad 2321, the second buffer pad 2322, the third buffer pad 2323, and the fourth buffer pad 2324.

The signal processing substrate 2330 is provided on the plate 2310. The signal processing substrate 2330 is provided at a center of the plate 2310. For example, the signal processing substrate 2330 may be a PCB substrate. A plurality of signal processing pads 2331 and the processor 2352 are mounted on the signal processing substrate 2330.

The plurality of signal processing pads 2331 is provided outside the signal processing substrate 2330. The plurality of signal processing pads 2331 is re made of a conductive material. For example, the plurality of signal processing pads 2331 may be formed of gold (Au). The plurality of signal processing pads 2331 is re electrically connected to a plurality of corresponding buffer pads 2320 through the wire WR.

The plurality of signal processing pads 2331 includes a first signal processing pad 2331a, a second signal processing pad 2331b, a third signal processing pad 2331c, and a fourth signal processing pad 2333d. Although only four signal processing pads are illustrated as the plurality of signal processing pads 2320 in the drawing, this is an example, and the signal processing pads 2330 may be provided in a number corresponding to the number of the plurality of buffer pads 2320.

The first signal processing pad 2331a and the second signal processing pad 2331b are provided at one side with respect to the center of the signal processing substrate 2330, and the third signal processing pad 2331c and the fourth signal processing pad 2331d are provided at one side with respect to the center of the signal processing substrate 2330.

The first signal processing pad 2331a, the second signal processing pad 2331b, the third signal processing pad 2331c, and the fourth signal processing pad 2331d correspond to the first buffer pad 2321, the second buffer pad 2322, the third buffer pad 2323, and the fourth buffer pad 2324, respectively.

The first signal processing pad 2331a, the second signal processing pad 2331b, the third signal processing pad 2331c, and the fourth signal processing pad 2331d are electrically connected to the first buffer pad 2321, the second buffer pad 2322, the third buffer pad 2323, and the fourth buffer pad 2324 through the wire WR. Here, the wire WR is connected to the inner portions 2321b, 2322b, 2323b and 2324b of the first buffer pad 2321, the second buffer pad 2322, the third buffer pad 2323, and the fourth buffer pad 2324.

The processor 2332 is provided in a central portion of the signal processing substrate 2330. For example, the processor 2332 may be a CPU, but is not limited thereto. The processor 2332 is electrically connected to the plurality of signal processing pads 2331. The processor 2332 processes the sensing values acquired by a plurality of sensor units 2320.

The cover 2340 is provided on the plate 2310. The cover 2340 covers the signal processing substrate 2330. The plate 2310 and the cover 2340 form an inner space. When viewed from above, the area of the cover 2340 is smaller than the area of the plate 2310.

The cover 2340 includes a sidewall 2341 covering both side surfaces of the signal processing substrate 2330 and an upper wall 2342 covering an upper portion thereof. When viewed from above, the width of the sidewall 2341 is narrower than the width of the plurality of buffer pads 2320, and the lower surface of the sidewall 2341 is in contact with the plurality of buffer pads 2320 to divide the plurality of buffer pads 2320 into an inner portion 2320a and an outer portion 2320b.

The heat insulation part 2350 is provided in the inner space of the signal processing unit 2300. The heat insulation part 2350 includes a first heat insulation part 2351 and a second heat insulation part 2352. The heat insulation part 2350 is made of an insulation material. For example, the heat insulation part 2350 may be made of a vacuum insulation material or an aerogel, but the present invention is not limited thereto.

The first heat insulation part 2351 is provided between the plate 2310 and the signal processing substrate 2330. When viewed from above, the area of the first heat insulation part 2351 is larger than the area of the signal processing substrate 2330. Both ends of the first heat insulation part 3251 are provided at the outer side of the plurality of buffer pads 2320.

As the first insulation part 2351 is provided between the plate 2310 and the signal processing substrate 2330, heat transfer from the base plate 2100 to the signal processing substrate 2330 may be minimized.

The second heat insulation part 2352 is provided on the sidewall 2341 of the cover 2340. The second heat insulation part 2352 surrounds at least a portion of the wire WR connecting the plurality of buffer pads 2320 and the plurality of signal processing pads 2331.

Heat transfer to the plurality of signal processing pads 2331 through the wire WR may be minimized by surrounding at least a portion of the wire WR connecting the plurality of buffer pads 2320 and the plurality of signal processing pads 2331.

The battery 2360 is provided in the inner space. Although it is illustrated that one battery 2360 is provided in an upper part of the inner space in the drawings, this is an example and the present invention is not limited thereto. The battery 2360 supplies power to the signal processing substrate 2330.

The plurality of legs 2370 is formed to extend downward from a lower surface of the plate 2310. Although the drawing illustrate that two legs 2370 are formed at both ends of the plate 2310, the present invention is not limited thereto, and a larger number of legs may be formed at positions capable of supporting the plate 2310. The signal processing substrate 2330 is spaced apart from the base plate 2110 by the plurality of legs 2370, and heat transfer from the base plate 2100 to the signal processing substrate 2330 may be minimized. Accordingly, heat resistance of the signal processing unit 2000 may be improved.

A method of measuring the temperature of the temperature measuring apparatus 2000 will be described as follows. The first sensor unit 2210 and the second sensor unit 2220 are configured identically, and the present invention will be described based on the first sensor unit 2210.

The sensing value sensed by the temperature sensor 2111 is transmitted to the first measurement pad 2111 and the second measurement pad 2112 through the first sensor pad 2212a and the second sensor pad 2212b. The sensing values transmitted to the first measurement pad 2111 and the second measurement pad 2112 are transmitted to the first signal measurement pad 2331a and the second signal measurement pad 2331b through the first buffer pad 2321 and the second buffer pad 2322. Thereafter, the sensing value is transmitted to the processor 2332 through the first signal measurement pad 2331a and the second signal measurement pad 2331b, and the processor 2332 processes the sensing value.

A method of setting a heating temperature of the heater 1320 using the temperature measuring apparatus according to an exemplary embodiment of the present invention is as follows.

The temperature measuring apparatus 2000 may be transferred from the sensor storage unit 350 to the baking unit 1000. Here, the temperature measuring apparatus may be transferred by the developing unit robot 482.

When the temperature measuring apparatus 2000 is transferred, the baking unit 1000 is heated to a preset temperature using the heater 1220. The temperature measuring apparatus 2000 measures the temperature of a plurality of regions of the base plate 2200 by using the plurality of sensor units 2200 provided on the base plate 2100. The temperature measuring apparatus 2000 transmits the measured value to a controller (not illustrated). The controller corrects a preset temperature of the heater 1220 based on the measured value. The temperature measuring apparatus 2000 is transferred to the sensor storage unit 350. Thereafter, the substrate W may be returned to the baking unit 1000, and the returned substrate W may be heat-treated in the baking unit 1000 according to the modified set temperature.

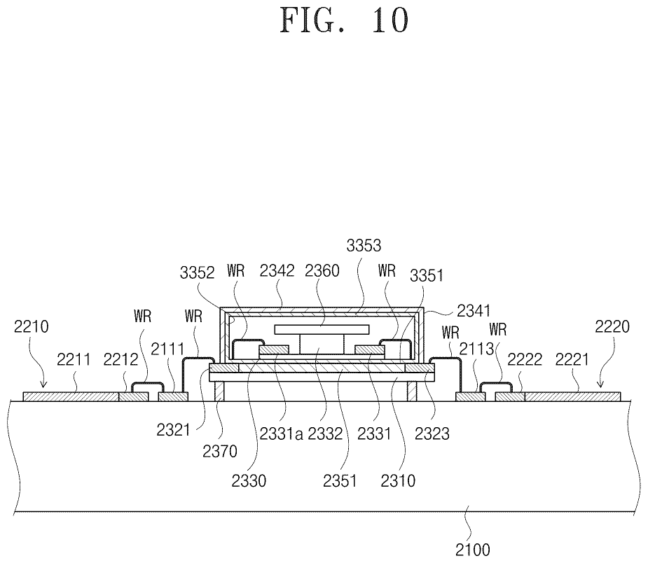

FIG. 10 is a top plan view of a temperature measuring apparatus according to another exemplary embodiment of the present invention.

Referring to FIG. 10, the temperature measuring apparatus 2000 includes a base plate 2100, a plurality of sensor units 2200, and a signal processing unit 3300. The signal processing unit 3300 includes a plate 2310, a plurality of buffer pads 2320, a signal processing substrate 2330, a cover 2340, a heat insulation part 3350, a battery 2360, and a plurality of legs 2370.

The heat insulation part 3350 includes a first heat insulation part 3351, a second heat insulation part 3352, and a third heat insulation part 3353. The first heat insulation part 3351 and the heat second insulation part 3352 are the same as the first heat insulation part 2351 and the heat second insulation part 2352 described above.

The third heat insulation part 2353 is provided inside the upper wall 2342 of the cover 2340. As the third heat insulation part 2353 is provided, the heat resistance of the temperature measuring apparatus 3000 may increase.

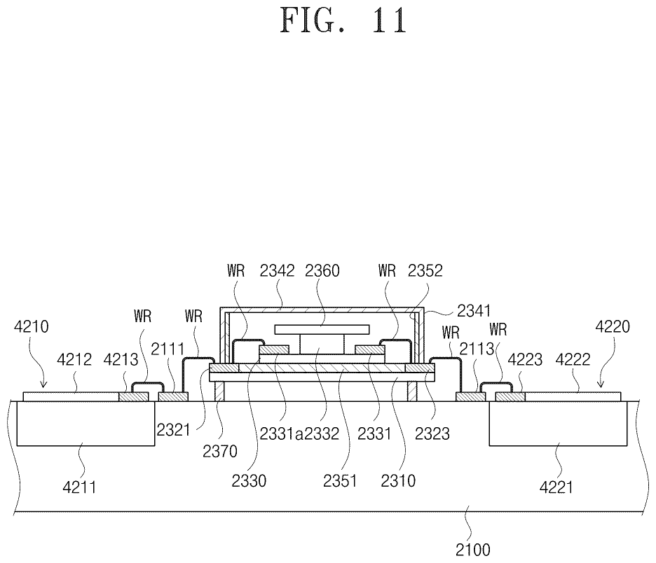

FIG. 11 is a top plan view of a temperature measuring apparatus according to still another exemplary embodiment of the present invention.

Referring to FIG. 11, a temperature measuring apparatus 4000 includes a base plate 2100, a plurality of sensor units 4200, and a signal processing unit 2300.

A plurality of sensor units 4200 includes a first sensor unit 4210 and a second sensor unit 4220. The first sensor unit 4210 includes a sensor substrate 4211 embedded in the base plate 2100, a temperature sensor 4212 mounted on the sensor substrate 4211, and a sensor pad 4213. Since the second sensor unit 4220 is configured in the same manner as the first sensor unit 4210, a description of the second sensor unit 4220 will be omitted.

Meanwhile, unlike the drawing, one of the first sensor unit 4210 and the second sensor unit 4220 may be configured in the same manner as the first sensor unit 2210 and the first sensor unit 2220 of FIG. 7.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. A temperature measuring apparatus comprising:
a base plate on which a plurality of measurement pads is formed;
a plurality of sensor units provided on the base plate and electrically connected to the corresponding measurement pad; and
a signal processing unit electrically connected to the measurement pads and configured to receive sensing values from the plurality of sensor units,
wherein the signal processing unit includes:
a plate;
a signal processing substrate provided on the plate, on which a processor configured to process the sensing value is mounted; and
a plurality of legs extending downward from a lower surface of the plate to separate the plate and the base plate from each other.

2. The temperature measuring apparatus of claim 1, wherein the signal processing unit further includes a first heat insulation part provided between the plate and the signal processing substrate.

3. The temperature measuring apparatus of claim 2, wherein wherein the signal processing unit further includes:
a plurality of buffer pads provided on the plate and electrically connected to the corresponding measurement pad through a first wire; and
a plurality of signal processing pads mounted on the signal processing substrate and electrically connected to the corresponding buffer pad through a second wire, and
the plurality of buffer pads is provided at an outer side than the first insulation part.

4. The temperature measuring apparatus of claim 3, wherein an area of the buffer pad is provided larger than an area of the corresponding measurement pad.

5. The temperature measuring apparatus of claim 3, wherein the signal processing unit further includes:
a cover provided on the plate to cover the signal processing substrate; and
a second heat insulation part provided on a sidewall of the cover, and
the second heat insulation part surrounds at least a part of the second wire.

6. The temperature measuring apparatus of claim 5, wherein when viewed from above, the sidewall of the cover is in contact with an upper surface of the buffer pad,
the buffer pad has an inner portion positioned inward of the sidewall and an outer portion positioned outward of the sidewall,
the first wire is connected to the outer portion, and
the second wire is connected to the inner portion.

7. The temperature measuring apparatus of claim 5, further comprising:
a third heat insulation part provided on an inner surface of an upper wall of the cover.

8. The temperature measuring apparatus of claim 1, wherein at least one of the plurality of sensor units includes:
a sensor substrate embedded in the base plate;
a temperature sensor mounted on the sensor substrate; and
a sensor pad electrically connected to the corresponding measurement pad through a third wire.

9. The temperature measuring apparatus of claim 1, wherein at least one of the plurality of sensor units includes:
a temperature sensor mounted on the base plate; and
a sensor pad electrically connected to the corresponding measurement pad through a fourth wire.

10. The temperature measuring apparatus of claim 1, wherein the signal processing unit further includes a battery that supplies power to the signal processing substrate.

11. An apparatus for processing a substrate, the apparatus comprising:
a chamber having an inner space formed;
a support unit provided in the inner space to support a substrate;
a heater configured to heat the substrate supported by the support unit; and
a temperature measuring apparatus provided to be supportable by the support unit and measuring temperature,
wherein the temperature measuring apparatus includes:
a base plate on which measurement pads are formed;
a plurality of sensor units provided on the base plate and electrically connected to the measurement pads; and
a signal processing unit electrically connected to the measurement pads and receiving sensing values from the plurality of sensor units, and
the signal processing unit includes:
a plate;
a signal processing substrate provided on the plate, on which a processor configured to process the sensing value is mounted; and
a plurality of legs extending downward from a lower surface of the plate to separate the plate and the base plate from each other.

12. The apparatus of claim 11, further comprising:
a plurality of buffer pads provided on the plate and electrically connected to the corresponding measurement pad through a first wire; and
a plurality of signal processing pads mounted on the signal processing substrate and electrically connected to the corresponding buffer pad through a second wire, and
a cover provided on the plate to cover the signal processing substrate; and
a first heat insulation part provided between the plate and the signal processing substrate; and
a second heat insulation part provided on a sidewall of the cover and surrounding a part of the second wire.

13. The apparatus of claim 12, wherein an area of the buffer pad is provided larger than an area of the measurement pad.

14. The apparatus of claim 12, further comprising:
a third heat insulation part provided on an inner side of an upper wall of the cover.

15. The apparatus of claim 11, wherein the buffer pad has an inner portion positioned inward of the sidewall and an outer portion positioned outward of the sidewall,
the first wire is connected to the outer portion, and
the second wire is connected to the inner portion.

16. The apparatus of claim 11, wherein at least one of the plurality of sensor units includes:
a sensor substrate embedded in the base plate;
a temperature sensor mounted on the sensor substrate; and
a sensor pad electrically connected to the corresponding measurement pad through a third wire.

17. The apparatus of claim 11, wherein at least one of the plurality of sensor units includes:
a temperature sensor mounted on the base plate; and
a sensor pad electrically connected to the corresponding measurement pad through a fourth wire.

18. The apparatus of claim 11, wherein the base plate has the same shape as the substrate.

19. A temperature measuring apparatus comprising:
a base plate on which a plurality of measurement pads is formed;
a plurality of sensor units provided on the base plate and electrically connected to the measurement pads; and
a signal processing unit electrically connected to the measurement pads and receiving sensing values from the plurality of sensor units, and
the signal processing unit includes:
a plate;
a plurality of buffer pads provided on the plate and electrically connected to the corresponding measurement pad through a first wire;
a signal processing substrate provided on the plate, on which a processor configured to process the sensing value is mounted;
a plurality of signal processing pads mounted on the signal processing substrate and electrically connected to the corresponding buffer pad through a second wire;
a cover provided on the plate to cover the signal processing substrate;
a first heat insulation part provided between the plate and the signal processing substrate;
a second insulation part provided on a sidewall of the cover and surrounding a part of the second wire;
a battery configured to supply power to the signal processing substrate; and
a plurality of legs extending downward from a lower surface of the plate to separate the plate and the base plate from each other, and
when viewed from above, the sidewall of the cover is in contact with an upper surface of the buffer pad,
the buffer pad has an inner portion positioned inward of the sidewall and an outer portion positioned outward of the sidewall,
the first wire is connected to the outer portion, and
the second wire is connected to the inner portion.

20. The temperature measuring apparatus of claim 19, wherein an area of the buffer pad is provided larger than an area of the corresponding measurement pad.
